(19) United States
(12) Patent Application Publication
(10) Pub. No.: US 2009/0206459 A1
(43) Pub. Date: Aug. 20, 2009

(54) QUAD FLAT NON-LEADED PACKAGE STRUCTURE

(75) Inventor: Cheng-Ting Wu, Tainan County (TW)

Correspondence Address: J C PATENTS, INC., 4 VENTURE, SUITE 250, IRVINE, CA, 92618, US

(73) Assignee: ChipMOS Technologies Inc., Hsinchu (TW)

(21) Appl. No.: 12/269,509

(22) Filed: Nov. 12, 2008

(30) Foreign Application Priority Data
Feb. 20, 2008 (TW) 97105927

(51) Int. Cl. H01L 23/495

(52) U.S. Cl. 257/676; 257/E23.031

(57) ABSTRACT

A quad flat non-leaded package structure including a die pad, a plurality of leads, a chip, and a molding compound is provided. The die pad has a top surface and an opposite bottom surface, and the leads are disposed around the die pad. A concave portion is disposed at the end of each leads. The chip is disposed on the top surface of the die pad and is electrically connected to the leads. The molding compound encapsulates the chip, a portion of the leads and the die pad, and fills the gaps between the leads.

### CROSS-REFERENCE TO RELATED APPLICATION

This application claims the priority benefit of Taiwan application serial no. 97105927, filed on Feb. 20, 2008. The entirety of the above-mentioned patent application is hereby incorporated by reference herein and made a part of specification.

### BACKGROUND OF THE INVENTION

1. Field of the Invention

The present invention relates to a chip package structure. More particularly, the present invention relates to a quad flat non-leaded (QFN) package structure.

2. Description of Related Art

In the semiconductor industry, the fabrication of integrated circuits (IC) can be divided into three phases: IC design, IC fabrication process, and IC packaging.

Regarding IC packaging, a chip is fabricated through wafer fabrication, circuit design, photolithography and etching processes, and wafer dicing, etc. Each chip is electrically connected to a substrate through a bonding pad on the chip, and the chip is encapsulated by a molding compound to form a chip package structure. The packaging process protects the chip from heat, humidity, and contamination and provides an electrical connection medium between the chip and external circuits.

FIG. 1A is a cross-sectional view of a conventional quad flat non-leaded (QFN) package structure (referred to as QFN package structure hereinafter). The conventional QFN package structure 100 includes a chip 110, a die pad 122, a plurality of leads 124, a plurality of bonding wires 130 and a molding compound 140. Each of the leads 124 has a top surface 123a and an opposite bottom surface 123b, and the leads 124 are disposed around the die pad 122. The chip 110 is disposed on the die pad 122, and is electrically connected to one of the leads 124 via one of the bonding wires 130. Moreover, the molding compound 140 encapsulates the chip 110, the bonding wires 130, the die pad 122 and a part of each lead 124.

Moreover, FIG. 1B and FIG. 1C are respectively a bottom view and a three-dimensional view of the QFN package structure of FIG. 1A. The bottom surfaces 123b of the leads 124 of the QFN package structure 100 are exposed outside the molding compound 140, and an end of each lead 124 is aligned to the side edge (shown as a region 150 circled by dot lines in FIG. 1B) of the molding compound 140, such that the leads 124 can serve as contact points of the chip package structure for external connection.

However, since the leads of the chip package structure are aligned to the quad of the molding compound, in a follow-up bonding process, a contact area between solder paste and the chip package structure only includes a bottom area of the leads, which may lead to a result that reliability of the bonding process is lowered. Moreover, such chip package structure may also cause a decrease of lifespan of a cutting tool. Therefore, the conventional chip package structure is required to be further improved.

### SUMMARY OF THE INVENTION

Accordingly, the present invention is directed to a QFN package structure, which may improve reliability of a bonding process, and damage of a cutting tool can be avoided, so that lifespan thereof can be prolonged.

The present invention provides a QFN package structure including a die pad, a plurality of leads, a chip, and a molding compound. The die pad has a top surface and an opposite bottom surface, and the leads are disposed around the die pad. An outer edge of an end of each lead has a concave portion. The chip is disposed on the top surface of the die pad and is electrically connected to the leads. Moreover, the molding compound encapsulates the chip, a portion of the leads and the die pad, and fills the gaps between the leads.

In an embodiment of the present invention, the molding compound is further disposed at the concave portion of the leads.

In an embodiment of the present invention, the concave portion of each of the leads is an arc concave portion.

In an embodiment of the present invention, the bottom surface of the die pad has a multi-step ladder-shape first opening, and/or an end of at least one lead located adjacent to the die pad has a multi-step ladder-shape second opening.

In an embodiment of the present invention, the QFN package structure further includes an adhesive layer disposed between the chip and the die pad, wherein material of the adhesive layer is for example, silver paste.

In an embodiment of the present invention, the QFN package structure further includes a plurality of bonding wires respectively connecting the chip and the leads. Wherein, material of the molding compound is polymer.

The present invention provides a lead frame including a die pad, a plurality of leads, a plurality of cutting channels. The leads are disposed around the die pad, and each of the cutting channels is connected to a portion of the leads. Wherein, a junction of each of the leads and each of the cutting channels has a through hole.

Since the outer edge of the end of each lead has the concave portion, reliability of a bonding process can be improved, and damage of a cutting tool can be avoided, so that lifespan thereof can be prolonged. Moreover, the bottom surface of the die pad and/or the end of at least one lead located adjacent to the die pad has a multi-step ladder-shape opening, which may increase a contact area with the molding compound, so that influence of the reliability due to invasion of vapor or contamination, or cracking of the molding compound can be avoided.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a cross-sectional view of a conventional QFN package structure.

FIG. 1B is a bottom view of the QFN package structure of FIG. 1A.

FIG. 1C is a three-dimensional view of the QFN package structure of FIG. 1A.

FIG. 2A is a cross-sectional view of a QFN package structure according to an embodiment of the present invention.

FIG. 2B is bottom view of the QFN package structure of FIG. 2A.

FIG. 2C is a top view of an amplified region of FIG. 2A.

FIG. 3 is a bottom view of the QFN package structure according to another embodiment of the present invention.

FIGS. 4A, 4B and 4C are cross-sectional views of a die pad and leads according to an embodiment of the present invention.

FIG. 5 is a schematic diagram of a die pad and leads of the present invention before cutting.

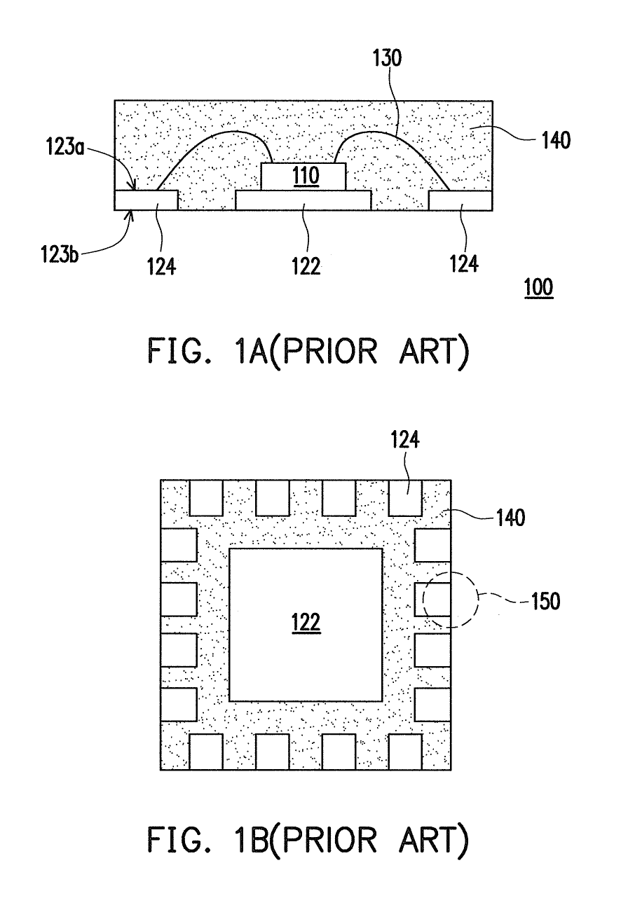

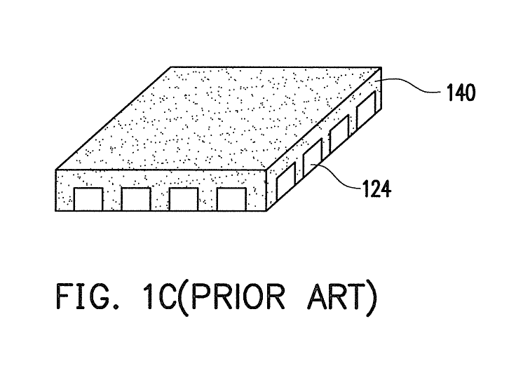

### DESCRIPTION OF EMBODIMENTS

In the following content, a plurality of package structures are taken as examples for describing the present invention, though these examples are not used for limiting the present invention.

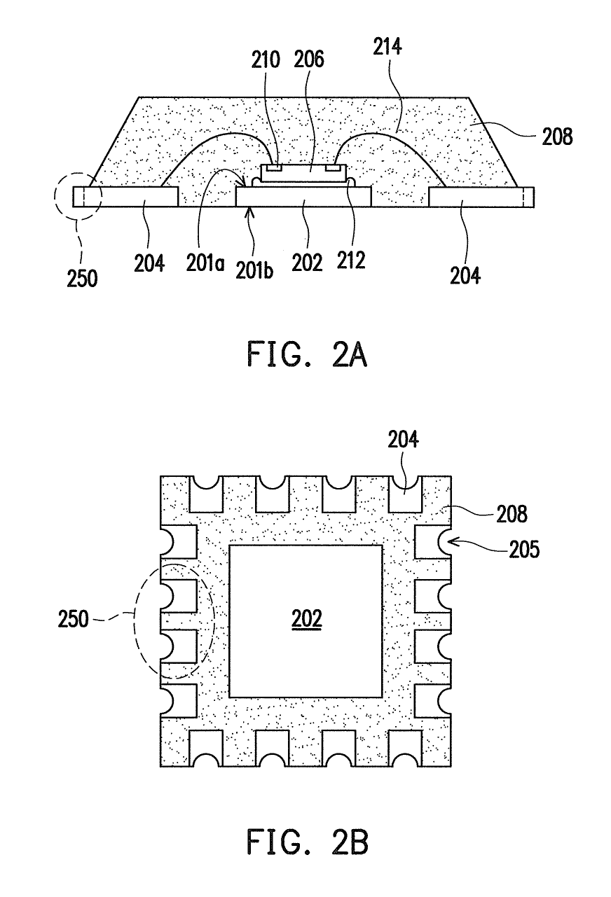

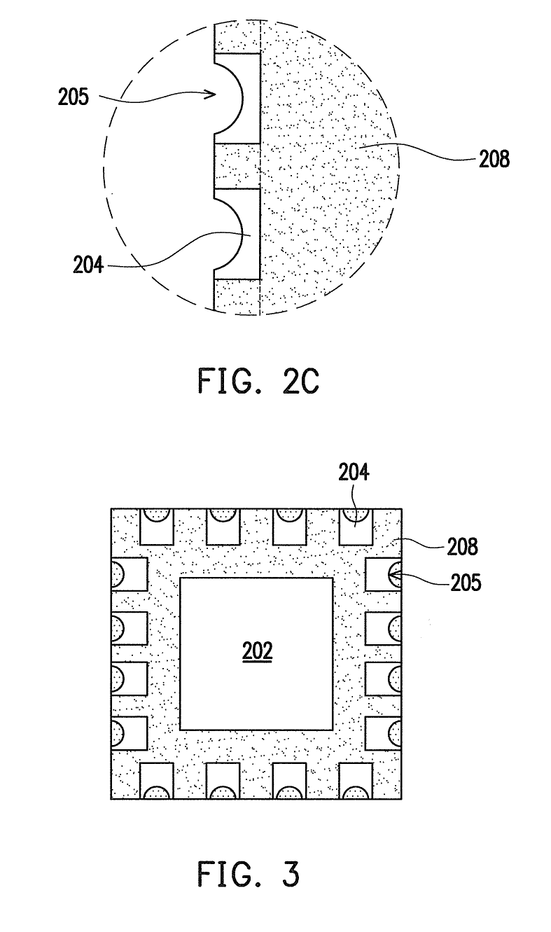

FIG. 2A is a cross-sectional view of a QFN package structure according to an embodiment of the present invention. FIG. 2B is bottom view of the QFN package structure of FIG. 2A.

Referring to FIG. 2A and FIG. 2B, the package structure includes a die pad 202, a plurality of leads 204, a chip 206 and a molding compound 208. The die pad 202 has a top surface 201a and an opposite bottom surface 201b, and the leads 204 are disposed around the die pad 202. Material of the die pad 202 and the leads 204 can be metal materials such as copper, copper alloy or nickel-iron alloy.

A plurality of bonding pads 210 can be disposed on the chip 206, and the chip 206 is disposed on the top surface 201a of the die pad 202. In an embodiment, an adhesive layer 212 can be disposed between the chip 206 and the die pad 202, and the chip 206 can be attached to the die pad 202 via the adhesive layer 212. The material of the adhesive layer 212 can be for example, silver paste. Moreover, the package structure of the present embodiment can also include a plurality of bonding wires 214. Each of the bonding wires 214 is connected to the bonding pad 210 of the chip 206 and one end of a lead 205 for electrically connecting the chip 206 to one of the leads 204. The material of the bonding wires 215 can be gold or other suitable conductive materials.

Moreover, the molding compound 208 encapsulates the chip 206, a portion of the leads 204 and the die pad 202, and exposes the bottom surface 201b of the die pad 202 and the bottom surface of the leads 204. The material of the molding compound 208 can be epoxy resin or other suitable polymer.

It should be noted that an outer edge of the end of each lead 204 has a concave portion 205 shown as a region 250 circled by dot lines in FIG. 2B. The concave portion 205 can be formed via a punch process. Moreover, the concave portion 205 of the lead 204 can be an arc concave portion. Certainly, size and shape of the concave portion 205 is not limited by the present invention, and minor variations thereof are still regarded to be within the scope of the present invention. Moreover, FIG. 2C is a top view of the amplified region 250 of FIG. 2A. As shown in FIG. 2C, the molding compound 208 can fill the gaps between the leads 204.

Therefore, compared to the conventional package structure, in a bonding process, besides a bottom area of the package structure, a contact area between solder paste and the package structure further includes side areas of the leads. Therefore, during a reflow process, the solder paste may flow to the side of the leads due to a siphon phenomenon, so as to improve a reliability of the bonding process.

In another embodiment, as shown in FIG. 3, the molding compound 208 is further disposed at the concave portion 205 of the lead 204. Therefore, such special design of the package structure of the present embodiment avails to avoid damage of a cutting tool, so that lifespan thereof can be prolonged.

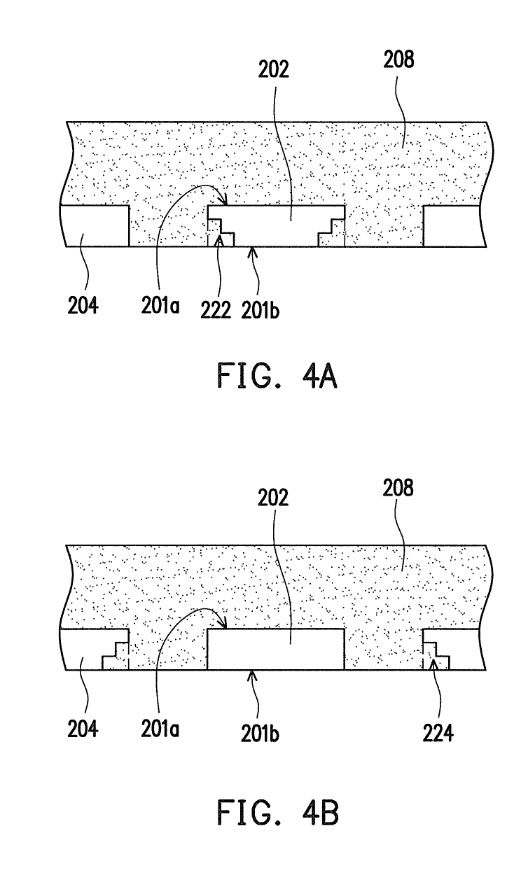

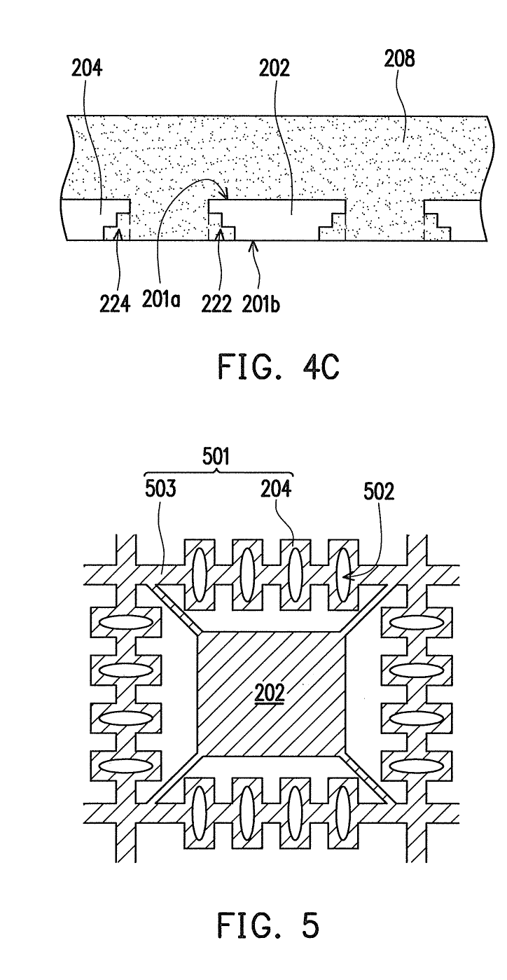

For still another embodiment, FIGS. 4A, 4B and 4C are cross-sectional views of a die pad and leads according to an embodiment of the present invention. For simplicity's sake, only the die pad, the leads and the molding compound are illustrated in figures, and other components are omitted.

As shown in FIG. 4A, the bottom surface 201b of the die pad 202 may have an opening 222. The opening 222 is a multi-step ladder-shape opening, i.e. the opening 222 is the ladder-shape opening with two or more steps. Accordingly, compared to the conventional package structure, such design may further increase the contact area with the molding compound. In other words, such design may increase a path length for the vapor or contamination entering an internal device region of the package structure, or increase a cracking path length of the molding compound, so as to avoid invasion of the vapor and the contamination, or the reduction of the reliability of the package structure caused by cracking of the molding compound. Moreover, as shown in FIG. 4B, one end of at least one lead 204 adjacent to the die pad 202 may have an opening 224, wherein the opening 224 is also a multi-step ladder-shape opening. As shown in FIG. 4C, the bottom surface 201b of the die pad 202 and one end of at least one lead 204 adjacent to the die pad 202 may respectively have the openings 222 and 224. Certainly, the openings 222 and 224 are two-step ladder-shape openings in these embodiments, though the shape and size of the openings 222 and 224 are not limited by the present invention.

Next, to fully convey the spirit of the present invention to those skilled in the art, a plurality of embodiments is provided to describe a fabrication method of the leads with the concave portions.

Taking the package structure of FIG. 2A as an example, the fabrication method thereof is as follows. After the conventional molding process is completed, a portion of the end of the lead 204 is removed via a punch process, so as to form the concave portion 205. Wherein, the conventional molding process is known by those skilled in the art, and therefore detailed description thereof will not be repeated.

Moreover, taking the structure of FIG. 3 as an example, the fabrication method thereof is as follows. A patterning process is performed to the metal material layer of a lead frame 501, so as to form the die pad 202, the leads 204 and cutting channels 503, wherein each of the cutting channels 503 is connected to a portion of the leads 204. Next, through holes 502 are formed in the leads 204 and the cutting channels 503 via an etching or a punch process (shown as FIG. 5). Next, processes such as die bonding, wire bonding, molding and cutting, etc. are sequentially performed to form the structure of FIG. 3. Wherein, the processes of die bonding, wire bonding, molding and cutting, etc. are know by those skilled in the art, and therefore detailed description thereof will not be repeated.

In summary, since the outer edge of the end of each lead has a special design of the concave portion, reliability of the bonding process can be improved, and since during the cutting, the metal part existed in the cutting channels is greatly reduced, the damage of the cutting tool can be reduced, so that lifespan thereof can be prolonged. Moreover, the bottom surface of the die pad and/or the end of at least one lead located adjacent to the die pad has the multi-step ladder-shape opening, which may increase a contact area with the molding compound, so that influence of the reliability due to invasion of vapor or contamination, or cracking of the molding compound can be avoided.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A quad flat non-leaded (QFN) package structure, comprising:
a die pad having a top surface and an opposite bottom surface;
a plurality of leads disposed around the die pad, wherein an outer edge of an end of each of the leads has a concave portion;
a chip disposed on the top surface of the die pad and electrically connected to the leads; and
a molding compound encapsulating the chip, a portion of the leads and the die pad, and the molding compound filling the gaps between the leads.

2. The QFN package structure as claimed in claim 1, wherein the molding compound is disposed at the concave portion of the leads.

3. The QFN package structure as claimed in claim 1, wherein the concave portion of each of the leads is an arc concave portion.

4. The QFN package structure as claimed in claim 1, wherein the bottom surface of the die pad has a multi-step ladder-shape first opening, and/or an end of at least one lead located adjacent to the die pad has a multi-step ladder-shape second opening.

5. The QFN package structure as claimed in claim 1 further comprising an adhesive layer disposed between the chip and the die pad.

6. The QFN package structure as claimed in claim 5, wherein a material of the adhesive layer comprises silver paste.

7. The QFN package structure as claimed in claim 1 further comprising a plurality of bonding wires respectively connecting the chip and the leads.

8. The QFN package structure as claimed in claim 1, wherein a material of the molding compound is polymer.

9. A lead frame, comprising:
a die pad;
a plurality of leads disposed around the die pad; and
a plurality of cutting channels, each of the cutting channels connecting a portion of the leads,
wherein a junction of each of the leads and each of the cutting channels has a through hole.
